(19) United States
(12) Patent Application Publication
(10) Pub. No.: US 2019/0064509 A1
(43) Pub. Date: Feb. 28, 2019

(54) VARIABLE FOCUS MIRROR AND OPTICAL SCANNING DEVICE

(71) Applicant: DENSO CORPORATION, Kariya-city, Aichi-pref. (JP)

(72) Inventors: Koichi OYAMA, Kariya-city (JP); Takashi KATSUMATA, Kariya-city (JP); Tetsuya ENOMOTO, Kariya-city (JP); Yumi MARUYAMA, Kariya-city (JP)

(73) Assignee: DENSO CORPORATION, Kariya-city, Aichi-pref. (JP)

(21) Appl. No.: 16/080,038

(22) PCT Filed: Jan. 12, 2017
(86) PCT No.: PCT/JP2017/000804

§ 371 Date: Aug. 27, 2018

(30) Foreign Application Priority Data
Feb. 29, 2016 (JP) 2016-037902

(51) Int. Cl. G02B 26/10; B81B 3/00; G02B 26/08

(52) U.S. Cl. CPC G02B 26/10; H01L 41/1876; G02B 26/0858; B81B 3/0097

(57) ABSTRACT

A variable focus mirror includes a base portion, a first piezoelectric element, a reflection surface portion, and a second piezoelectric element. The base portion has a plate shape with a recessed portion on a back surface. The first piezoelectric element is arranged on a front surface of the base portion where the recessed portion is arranged. The reflection surface portion is arranged on the first piezoelectric element. The reflection surface portion is arranged opposite to the base portion with respect to the first piezoelectric element. The second piezoelectric element is arranged on the front surface of the base portion. The second piezoelectric element covers the part of the base portion where the recessed portion is arranged and the part of the base portion outside the recessed portion. The second piezoelectric element is separated from the first piezoelectric element.

### CROSS REFERENCE TO RELATED APPLICATION

This application is based on Japanese Patent Application No. 2016-37902 filed on Feb. 29, 2016, the disclosure of which is incorporated herein by reference.

### TECHNICAL FIELD

The present disclosure relates to a variable focus mirror and an optical scanning device.

### BACKGROUND ART

A MEMS (Micro Electro Mechanical Systems) optical scanning device includes a mirror and a support beam that supports the mirror at both ends. The MEMS optical scanning device scans a light beam by rotating the mirror around an axis of the support beam.

One of the optical scanning devices includes a bifocal MEMS mirror that changes a focal position of reflected light by being bent. For example, in Patent Document 1, a variable focus optical device has been proposed. In the variable focus optical device, a reflection surface portion is arranged on a piezoelectric element, and a voltage is applied to the piezoelectric element. In this configuration, the variable focus optical device changes a focal position of the reflected light by bending the reflection surface portion along with the piezoelectric element.

### PRIOR ART LITERATURE

### Patent Literature

Patent Literature 1: JP 2014-215399 A

### SUMMARY OF INVENTION

A focal position of reflected light is changed based on a curvature of a reflection surface portion. The curvature of the reflection surface portion is changed by a voltage applied to a piezoelectric element. In a variable focus optical scanning device, in order to precisely control the focal position of the reflected light and perform a scan with a high precision, it is important to have little variation of characteristics of the curvature of the reflection surface portion with respect to the applied voltage to the piezoelectric element.

It is an object of the present disclosure to provide a variable focus mirror and an optical scanning device each of which is capable of suppressing variation in characteristics.

According to an aspect of the present disclosure, a variable focus mirror includes a base portion, a first piezoelectric element, a reflection surface portion, and a second piezoelectric element. The base portion has a plate shape with a recessed portion on a back surface. A thickness of a part of the base portion where the recessed portion is arranged being smaller than a thickness of a part of the base portion outside the recessed portion. The first piezoelectric element is arranged on a front surface of the base portion where the recessed portion is arranged. The reflection surface portion is arranged on the first piezoelectric element. The reflection surface portion is arranged opposite to the base portion with respect to the first piezoelectric element. The second piezoelectric element is arranged on the front surface of the base portion. The second piezoelectric element covers the part of the base portion where the recessed portion is arranged and the part of the base portion outside the recessed portion. The second piezoelectric element is separated from the first piezoelectric element. Each of a film stress of the first piezoelectric element and a film stress of the second piezoelectric element is identical to a tensile direction or a compression direction.

With the above-described configuration, when the film stress of the first piezoelectric element is changed based on a temperature change or the like, the film stress of the second piezoelectric element similarly changes. The part of the base portion where the second piezoelectric element is arranged is deformed so as to suppress the deformation of the reflection surface portion based on the film stress of the first piezoelectric element. Thus, the deformation of the reflection surface portion based on the temperature change or the like can be suppressed, and the variation in the characteristics can be suppressed.

### BRIEF DESCRIPTION OF DRAWINGS

FIG. 1 is a diagram showing a plan view of a variable focus mirror according to a first embodiment.

FIG. 2 is a diagram showing a cross-sectional view taken along line II-II of FIG. 1.

FIG. 3 is a diagram showing a relationship between a voltage applied to a piezoelectric element and a curvature of a reflection surface portion.

FIG. 4 is a diagram showing a cross-sectional view indicative of an operation of the variable focus mirror.

FIG. 5 is a diagram showing a cross-sectional view according to a modified example of the first embodiment, which corresponds to FIG. 2.

FIG. 6 is a diagram showing a plan view of a variable focus mirror according to a second embodiment.

FIG. 7 is a diagram showing a plan view of a variable focus mirror according to a third embodiment.

FIG. 8 is a diagram showing a plan view of a variable focus mirror according to a fourth embodiment.

FIG. 9 is a diagram showing a plan view according to a modified example of the fourth embodiment.

FIG. 10 is a diagram showing a plan view of a variable focus mirror according to a fifth embodiment.

FIG. 11 is a timing diagram showing voltages applied to the two piezoelectric elements.

### EMBODIMENTS FOR CARRYING OUT INVENTION

Hereinafter, embodiments of the present disclosure will be described with reference to the drawings. In the following embodiments, the same or equivalent parts are denoted by the same reference numerals as each other, and explanations will be provided to the same reference numerals.

### First Embodiment

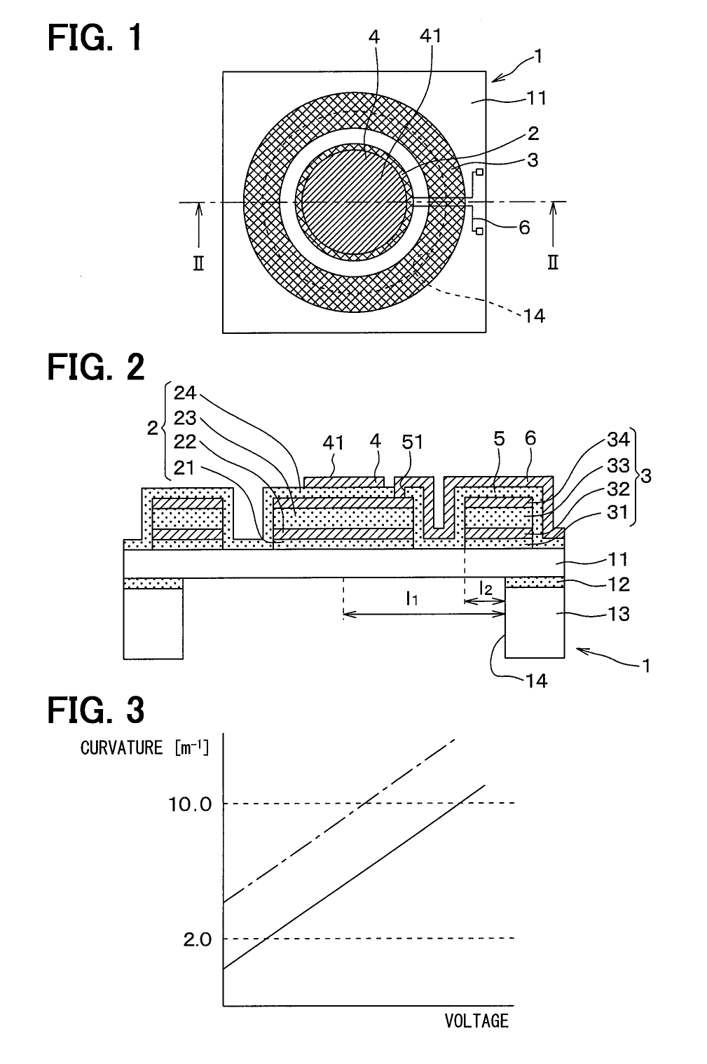

A first embodiment will be described. As shown in FIG. 1 and FIG. 2, a variable focus mirror of the present embodiment includes a base portion 1 that has a plate shape, a piezoelectric element 2, a piezoelectric element 3, a reflection portion 4, an insulating film 5, and a wiring 6. FIG. 1 does not show a cross-sectional view, but in order to cause FIG. 1 to be easily recognized, hatching is applied to the piezoelectric element 2, the piezoelectric element 3, and the reflection portion 4. In FIG. 1, the insulating film 5 is not shown.

In the present embodiment, as shown in FIG. 2, the base portion 1 is formed by an SOI (Silicon on Insulator) substrate in which an active layer 11, a sacrifice layer 12, and a support layer 13 are stacked in a described order. The active layer 11 and the support layer 13 may be made of Si. The sacrifice layer 12 may be made of SiO₂.

On a back surface of the base portion 1, a part of the sacrifice layer 12 and a part of the support layer 13 are removed to form a recessed portion 14. The recessed portion 14 opens on a back surface of the support layer 13. The thickness of a part of the base portion 1 where the recessed portion 14 is arranged is smaller than the thickness of a part of the base portion 1 outside the recessed portion 14.

The piezoelectric element 2 is arranged on a front surface of the base portion 1 where the recessed portion 14 is arranged on the back surface. Specifically, in the piezoelectric element 2, an insulating layer 21, a lower electrode 22, a piezoelectric film 23, and an upper electrode 24 are stacked on the front surface of the active layer 11 in a described order. The piezoelectric element 2 corresponds to a first piezoelectric element.

The piezoelectric element 3 is arranged on the front surface of the base portion 1, and covers the part of the base portion 1 where the recessed portion 14 is arranged and the part of the base portion 1 outside the recessed portion 14. The piezoelectric element 3 is separated from piezoelectric element 2. In the piezoelectric element 3, an insulating layer 31, a lower electrode 32, a piezoelectric film 33, and an upper electrode 34 are stacked on the front surface of the active layer 11 in a described order. The piezoelectric element 3 corresponds to a second piezoelectric element.

In the present embodiment, the insulating layers 21, 31 are made of SiO₂, and the lower electrodes 22, 32 are formed of a layered structure of SRO/Pt/Ti. The piezoelectric films 23, 33 are made of PZT (lead zirconate titanate), and the upper electrodes 24, 34 are formed of a layered structure of Ti/Au/Ti.

In the present embodiment, the direction of the film stress of the piezoelectric element 3 is set to be equal to the direction of the film stress of the piezoelectric element 2. The film stress of the piezoelectric element 2 and the film stress of the piezoelectric element 3 are set to the film stress in the tensile direction, or set to the film stress in the compression direction. In the present embodiment, the piezoelectric element 2 and the piezoelectric element 3 are made of the same material. With this configuration, the direction of the film stress of the piezoelectric element 3 is set to be equal to the direction of the film stress of the piezoelectric element 2.

The reflection portion 4 is arranged opposite to the base portion 1 with respect to the piezoelectric element 2. Specifically, as shown in FIG. 2, an insulating film 5 is arranged on the surfaces of the active layer 11, the piezoelectric element 2, and the piezoelectric element 3. The reflection portion 4 is provided by a thin film that is arranged on a surface of the insulating film 5 on the piezoelectric element 2. The reflection portion 4 has a reflection surface portion 41 which is the surface located opposite to the piezoelectric element 2. The reflection portion 4 reflects the light beam on the reflection surface portion 41. The reflection portion 4 may be made of Ag. The insulating film 5 may be made of SiO₂.

As shown in FIG. 1, in the present embodiment, the reflection surface portion 41 has a circular shape. Each of an upper surface of the piezoelectric element 2 and an upper surface of the recessed portion 14 has a circular shape. An upper surface of the piezoelectric element 3 has a ring shape. In the surface of the reflection surface portion 41, a center of the upper surface of the piezoelectric element 2, a center of the upper surface of the piezoelectric element 3, and a center of the upper surface of the recessed portion 14 are located at the same position as a center of the reflection surface portion 41.

As shown in FIG. 2, in the insulating film 5, an opening 51, which is located on the upper part of the piezoelectric element 2 and is distant from the reflection portion 4, is arranged to expose the upper electrode 24. The wiring 6 is arranged on the surface of the insulating film 5. The upper electrode 24 is connected to the wiring 6 at the opening 51 and connected to an external circuit through the wiring 6. On the insulating film 5, an opening, which is not shown in the figures, is arranged for exposing the lower electrode 22. The lower electrode 22 is connected to the wiring 6 at the opening, and connected to an external circuit through the wiring 6. The wiring 6 may be made of Al.

The piezoelectric elements 2, 3, the insulating film 5, the reflection portion 4, and the wiring 6 is arranged on the surface of the active layer 11 by photolithography or etching and the recessed portion 14 is arranged by removing a part of the sacrifice layer 12 and a part of the supporting layer 13 so that the variable focus mirror is manufactured. In the present embodiment, the piezoelectric element 2 and the piezoelectric element 3 are formed by the same process.

The variable focus mirror according to the present embodiment is used together with a light source and an optical scanning device, each of which is not shown in the figures. Specifically, when a light beam is irradiated from a light source, which is not shown in the figures, to the variable focus mirror, the light beam is reflected on the reflection surface portion 41 and is irradiated on an optical scanning device, which is not shown in the figures. The optical scanning device, which is not shown in the figures, includes a mirror that is supported at both ends by a beam and is swingable. The light beam is irradiated to the swinging mirror, and the light beam is scanned by being reflected.

When a voltage is applied to the lower electrode 22 and the upper electrode 24 of the piezoelectric element 2, the piezoelectric film 23 is deformed and the reflection surface portion 41 is bent. With this configuration, the focal position of the reflected light is changed.

The focal position of the reflected light is changed based on a curvature of the reflection surface portion 41. The curvature of the reflection surface portion 41 is changed based on the voltage applied to the piezoelectric element 2. Thus, in order to precisely control the focal position of the reflected light and perform the scan with a high precision, it is important to have little variation of the curvature of the reflection surface portion 41 with respect to the applied voltage to the piezoelectric element 2.

Specifically, as indicated by the solid line in FIG. 3, the curvature of the reflection surface portion 41 increases with an increase of the voltage applied to the piezoelectric element 2. In this configuration, as characteristics, it is required that the curvature in a state where no voltage is applied may be equal to or less than 2.0 m⁻¹, and the curvature in the state where the voltage is applied may be equal to or more than 10.0 m⁻¹.

In addition to the application of the voltage to the piezoelectric element 2, the reflection surface portion 41 is also deformed by the film stress of the piezoelectric element 2. The film stress in the tensile direction may be generated in the piezoelectric element 2 based on a difference between the temperature at the time of film formation of the piezoelectric element 2 and the environmental temperature at the time of use of the variable focus mirror. In this case, the active layer 11 and the reflection surface portion 41 are deformed to protrude toward the support layer 13. That is, the curvature of the reflection surface portion 41 increases.

As indicated by the dashed-dotted line in FIG. 3, the curvature in the state where no voltage is applied to the piezoelectric element 2 becomes more than 2.0 m⁻¹ when the characteristic of the curvature of the reflection surface portion 41 with respect to the voltage applied to the piezoelectric element 2 is changed.

With the above-described configuration, based on the film stress of the piezoelectric element 2, the characteristic of the curvature of the reflection surface portion 41 with respect to the voltage applied to the piezoelectric element 2 may have the variation.

In the present embodiment, the piezoelectric element 3 is arranged on the front surface of the base portion 1, and covers the part of the base portion 1 where the recessed portion 14 is arranged and the part of the base portion 1 outside the recessed portion 14. The piezoelectric element 3 is separated from piezoelectric element 2. The direction of the film stress of the piezoelectric element 3 is set to be equal to the direction of the film stress of the piezoelectric element 2.

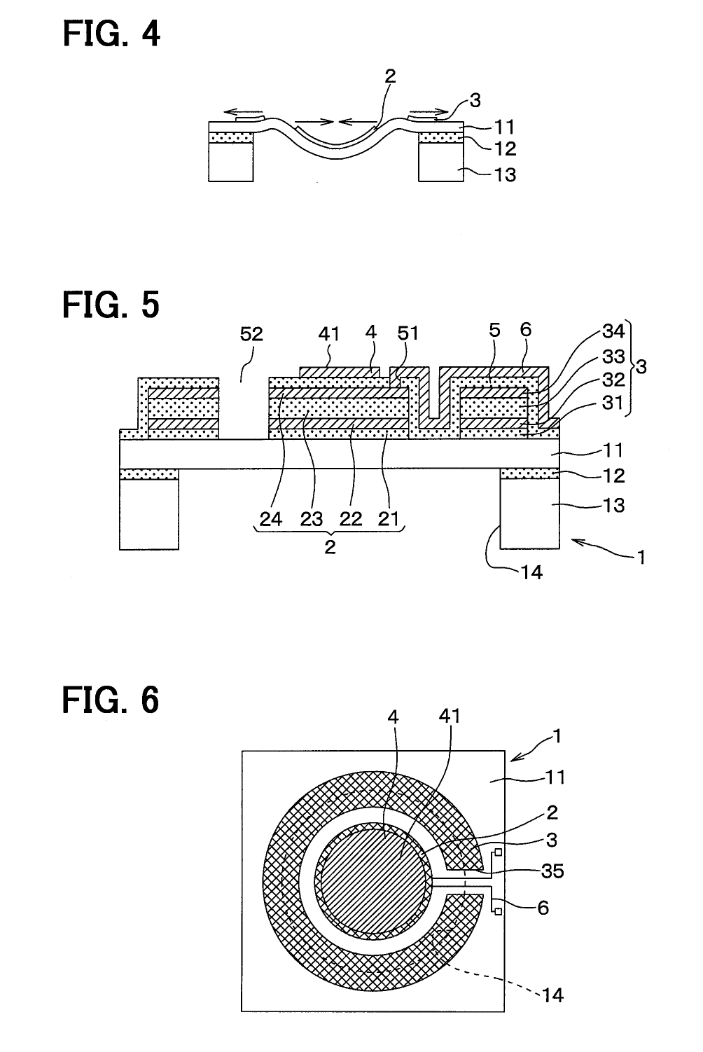

With the above-described configuration, in an environment where the film stress is generated in the piezoelectric element 2, the film stress in the same direction as the piezoelectric element 2 is generated in the piezoelectric element 3. For example, when the film stress in the tensile direction is generated in the piezoelectric element 2, the film stress in the tensile direction is also generated in the piezoelectric element 3. As shown in FIG. 4, the piezoelectric element 3 and the active layer 11 located under the piezoelectric element 3 are deformed to protrude toward the support layer 13.

The part of the base portion 1 outside the recessed portion 14 is thicker than the part of the base portion 1 where the recessed portion 14 is arranged. Thus, the part of the base portion 1 outside the recessed portion 14 is harder to be deformed than the part of the base portion 1 where the recessed portion 14 is arranged. With the deformation of the piezoelectric element 3, a part of the active layer 11 sandwiched between the recessed portion 14 and the piezoelectric element 3 is displaced toward the opposite direction of which the support layer 13 and the piezoelectric element 2 are displaced. With this configuration, to an outer radial direction, a force pulling the part of the active layer 11 where the piezoelectric element 2 is arranged is generated. Thus, an increase in the curvature of the reflection surface portion 41 based on the film stress of the piezoelectric element 2 is suppressed.

In the present embodiment, the piezoelectric element 2 and the piezoelectric element 3 are formed by the same process. With this configuration, when the film stress of the piezoelectric element 2 has the variation based on the film forming temperature or the like, the film stress of the piezoelectric element 3 also has the similar variation. Thus, it is possible to suppress the increase in the curvature of the reflection surface portion 41 based on the film stress of the piezoelectric element 2 by the film stress of the piezoelectric element 3.

When the film stress of the piezoelectric element 2 is changed based on a change in the environmental temperature, the film stress of the piezoelectric element 3 similarly changes. Thus, it is possible to suppress the increase in the curvature of the reflection surface portion 41 based on the film stress of the piezoelectric element 2 by the film stress of the piezoelectric element 3.

As described above, in the present embodiment, the bending of the reflection surface portion 41 based on the film stress of the piezoelectric element 2 is suppressed by the film stress of the piezoelectric element 3. In this configuration, the variation in the characteristics of the variable focus mirror can be suppressed. The configuration can improve accuracy of the variable focus mirror.

In order to enhance the above-described advantages, it is preferable that the width of the piezoelectric element 3 is large. Specifically, as shown in FIG. 2, when the radius of the recessed portion 14 is defined as I₁ and the width of the part of the piezoelectric element 3 corresponding to the recessed portion 14 in the radial direction is defined as I₂, I₂ is equal to or more than 15% of I₁.

The insulating film 5 made of SiO₂ has a film stress in the compression direction. When the insulating film 5 is arranged on the surface of the active layer 11, the advantages obtained by the deformation of the active layer 11 based on the film stress in the tensile direction of the piezoelectric element 3 is suppressed. Thus, it is preferable to set the insulating film 5 arranged on the surface of the active layer 11 to be thin.

As shown in FIG. 5, it is preferable that an opening 52 is arranged on the insulating film 5. The opening 52 exposes a part of the base portion 1 located between the piezoelectric element 2 and the piezoelectric element 3. In a modified example shown in FIG. 5, the opening 52 is not arranged in a part of the insulating film 5 located under the wiring 6. Thus, the electrical insulation between the wiring 6 and the active layer 11 or the like is maintained.

### Second Embodiment

A second embodiment will be described. In the present embodiment, a shape of a piezoelectric element 3 is different from the first embodiment. Since the other parts are similar to the first embodiment, parts difference from the first embodiment will be described.

As shown in FIG. 6, in a piezoelectric element 3 of the present embodiment, a notch portion 35 is arranged. The notch portion 35 causes the surface of the active layer 11 of the base portion 1 to be exposed. Thus, the notch portion 35 connects a part of the surface of the base portion 1 corresponding to the inside of the recessed portion 14 with a part of the surface of the base portion 1 corresponding to the outside of the recessed portion 14. FIG. 6 does not show a cross-sectional view, but in order to cause FIG. 6 to be easily recognized, hatching is applied to the piezoelectric element 2, the piezoelectric element 3, and the reflection portion 4. In FIG. 6, the insulating film 5 is not shown.

The insulating film 5 is arranged on a surface of the notch portion 35. The wiring 6 is arranged so as to pass through the surface of the insulating film 5 arranged on the notch portion 35.

The wiring 6 may be arranged so as to pass through the upper part of the piezoelectric element 3. In this case, the wiring 6 is bent at a part where the wiring 6 extends from a bottom part of the insulating film 5, which corresponds to the recessed portion 14, to a top part of the insulating film 5 and a part where the wiring 6 extends from the top part of the insulating film 5 to the bottom part of the insulating film 5, which corresponds to the outside of the recessed portion 14. In this configuration, durability of the wiring 6 is lowered. Thus, there is a possibility that the wiring 6 is broken when the active layer 11 is deformed. A part of the insulating film 5 arranged on the surface of the active layer 11 is defined as the bottom part. A part of the insulating film 5 arranged on the surface of the upper electrode 34 is defined as the top part.

In the present embodiment, the wiring 6 is arranged so as to pass through the notch portion 35. Thus, the bending of the wiring 6 is suppressed, and the durability of the wiring 6 is improved. The configuration can suppress the break of the wiring 6, and improve accuracy of the variable focus mirror.

### Third Embodiment

A third embodiment will be described. In the present embodiment, a shape of a piezoelectric element 2 is different from the second embodiment. Since the other parts are similar to the second embodiment, parts difference from the second embodiment will be described.

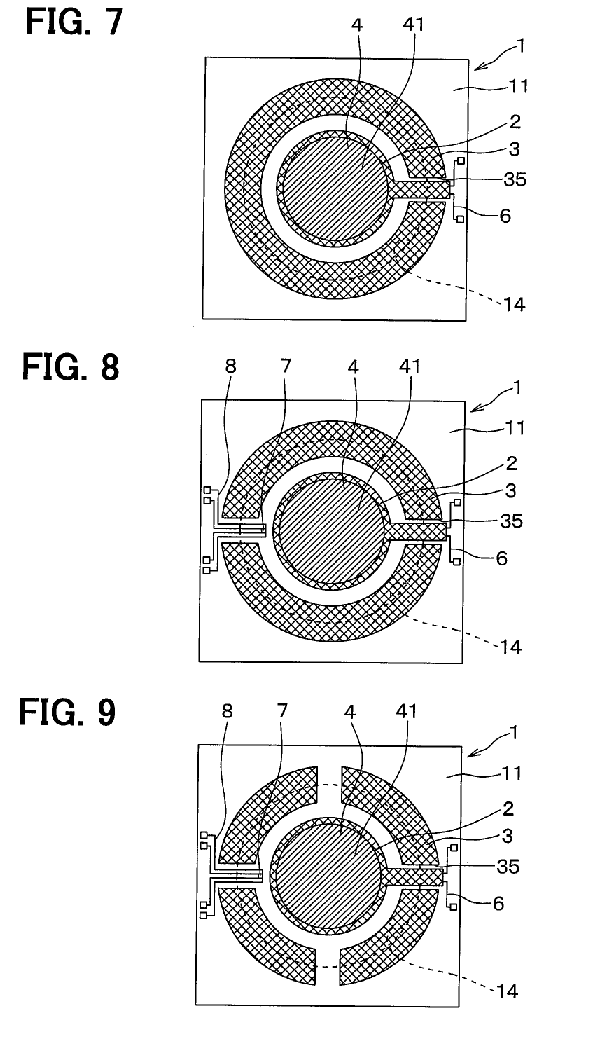

As shown in FIG. 7, a piezoelectric element 2 of the present embodiment has a part that extends to the outside of the recessed portion 14 through the notch portion 35. The opening 51 is arranged on a part of the insulating film 5 corresponding to the outside of the recessed portion 14. The upper electrode 24 and the wiring 6 are connected at a point outside the recessed portion 14. The opening, which is not shown in the figures, exposing the lower electrode 22 is arranged on a part of the insulating film 5 corresponding to the outside of the recessed portion 14. The lower electrode 22 and the wiring 6 are connected at a point outside the recessed portion 14. FIG. 7 does not show a cross-sectional view, but in order to cause FIG. 7 to be easily recognized, hatching is applied to the piezoelectric element 2, the piezoelectric element 3, and the reflection portion 4. In FIG. 7, the insulating film 5 is not shown.

The part of the base portion 1 outside the recessed portion 14 is thicker than the part of the base portion 1 where the recessed portion 14 is arranged. Thus, the part of the base portion 1 outside the recessed portion 14 is harder to be deformed than the part of the base portion 1 where the recessed portion 14 is arranged. As described above, the upper electrode 24 and the lower electrode 22 are respectively connected to the wiring 6 at points outside the recessed portion 14. Thus, the durability of the connecting parts between the upper electrode 24 and the wiring 6 and between the lower electrode 22 and the wiring 6 are improved. With this configuration, poor connection between the upper electrode 24 and the wiring 6 and between the lower electrode 22 and the wiring 6 based on the deformation of the active layer 11 can be suppressed, and the reliability of the variable focus mirror can be improved.

### Fourth Embodiment

A fourth embodiment will be described. In the present embodiment, a sensor is added to the configuration of the third embodiment. Since the other parts are similar to the third embodiment, parts difference from the third embodiment will be described.

As shown in FIG. 8, a variable focus mirror of the present embodiment includes a strain gauge 7 and a wiring 8. FIG. 8 does not show a cross-sectional view, but in order to cause FIG. 8 to be easily recognized, hatching is applied to the piezoelectric element 2, the piezoelectric element 3, and the reflection portion 4. In FIG. 8, the insulating film 5 is not shown.

The strain gauge 7 is a sensor for detecting the curvature of the reflection surface portion 41. The strain gauge 7 is formed by performing ion implantation of a semiconductor impurity into the surface of the part of the base portion 1 where the recessed portion 14 is arranged.

In the piezoelectric element 3 of the present embodiment, two notch portions 35 are arranged. The piezoelectric element 2 is located between the two notch portions 35. The upper surface of the piezoelectric element 3 has a point symmetry shape with respect to the center of the reflection portion 41. Similarly to the second embodiment, an extended part of the piezoelectric element 2 is located in one of the notch portions 35. A wiring 8 is provided on the surface of the insulating film 5 arranged on another one of the notch portions 35.

The wiring 8 connects the strain gauge 7 with an external circuit. The wiring 8 may be made of Al. The insulating film 5 is also arranged on the surface of the strain gauge 7 in addition to the surfaces of the active layer 11 and the piezoelectric elements 2, 3. On the insulating film 5, an opening, which is not shown in figures, is arranged to expose the surface of the strain gauge 7. The wiring 8 is connected to the strain gauge 7 at the opening. The wiring 8 is arranged so as to extend from the opening to the outside of the piezoelectric element 3 through the notch portion 35.

With this configuration, based on the bending of the active layer 11 and the reflection surface portion 41, the strain gauge 7 is deformed and the resistance value of the strain gauge 7 changes. The curvature of the reflection surface portion 41 is capable of being detected by obtaining the change in the resistance value through the wiring 8.

In the present embodiment, the strain gauge 7 is located on the part of the base portion 1 where the recessed portion 14 is arranged. The notch portion 35 is arranged in the piezoelectric element 3, and the wiring 8 is arranged so as to connect the strain gauge 7 with the external circuit by passing through the notch portion 35. With this configuration, the durability of the wiring 8 is improved, similarly to the second embodiment. The configuration can improve the accuracy of the variable focus mirror.

A shape of a cross section of the reflection surface portion 4 in a plane passing through the center of the reflection surface portion 41 and parallel to the thickness direction of the base portion 1 is prevented from greatly changing corresponding to an angle of the plane. Thus, it is preferable that the upper surface of the piezoelectric element 3 has a rotational symmetry shape with respect to the center of the surface 41.

For example, when the notch portion 35 is arranged in the piezoelectric element 3, it is preferable that the upper surface of the piezoelectric element 3 has the point symmetry shape by forming two notch portions 35 on both sides of the reflection portion 4, as described in the present embodiment. As shown in FIG. 9, notch portions 35 are arranged on both sides of the reflection portion 4 in two directions parallel to the surface of the base portion 1 and perpendicular to each other. In this case, the notch portions 35 divide the piezoelectric element 3 into four sections. As described above, it is more preferable that the upper surface of the piezoelectric element 3 has a four-fold rotational symmetry shape. FIG. 9 does not show a cross-sectional view, but in order to cause FIG. 9 to be easily recognized, hatching is applied to the piezoelectric element 2, the piezoelectric element 3, and the reflection portion 4. In FIG. 9, the insulating film 5 is not shown.

### Fifth Embodiment

A fifth embodiment will be described. In the present embodiment, a wiring is added to the configuration of the first embodiment. Since the other parts are similar to the first embodiment, parts difference from the first embodiment will be described.

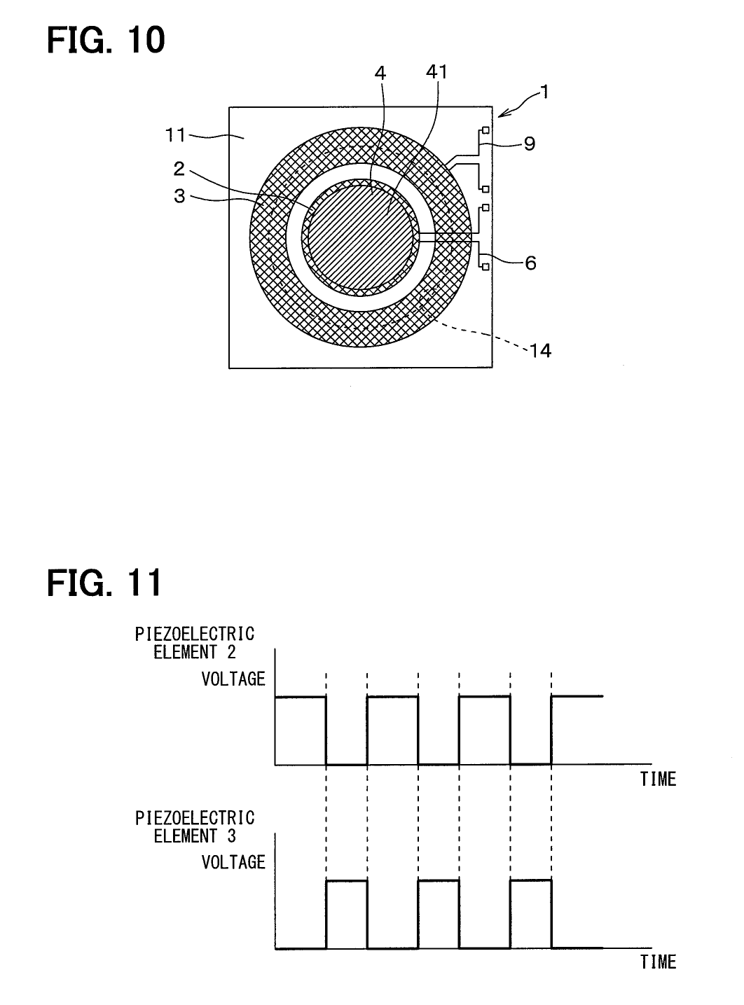

As shown in FIG. 10, a variable focus mirror of the present embodiment includes a wiring 9. FIG. 10 does not show a cross-sectional view, but in order to cause FIG. 10 to be easily recognized, hatching is applied to the piezoelectric element 2, the piezoelectric element 3, and the reflection portion 4. In FIG. 10, the insulating film 5 is not shown. The wiring 9 connects the piezoelectric element 3 with an external circuit, and enables application of a voltage to the piezoelectric element 3. The wiring 9 may be made of Al.

In the present embodiment, as shown in FIG. 11, a voltage is applied to the piezoelectric element 3. When the voltage applied to the piezoelectric element 2 is in on state, the voltage applied to the piezoelectric element 3 is in off state. When the voltage applied to the piezoelectric element 2 is in off state, the voltage applied to the piezoelectric element 3 is in on state.

When the voltage applied to the piezoelectric element 2 is turned off in order to cause the reflection surface portion 41 to be flat, the voltage applied to the piezoelectric element 3 is turned on. In this configuration, to the outer radial direction, the force pulling the part of the active layer 11 where the piezoelectric element 2 is arranged increases. Thus, the increase in the curvature of the reflection surface portion 41 based on the film stress of the piezoelectric element 2 is suppressed.

When the voltage applied to the piezoelectric element 2 is turned on in order to cause the reflection surface portion 41 to be bent, the voltage applied to the piezoelectric element 3 is turned off. In this configuration, to the outer radial direction, the force pulling the part of the active layer 11 where the piezoelectric element 2 is arranged decreases. Thus, the curvature of the reflection surface portion 41 is likely to increase.

As described above, in the present embodiment, by applying the voltage to the piezoelectric element 3 through the wiring 9, the variation in the characteristics can be suppressed.

### Other Embodiments

The present disclosure is not limited to the above-described embodiments, and can be appropriately modified. Individual elements or features of a particular embodiment are generally not limited to that particular embodiment, but, where applicable, are interchangeable and can be used in a selected embodiment, even if not specifically shown or described. The constituent element(s) of each of the above embodiments is/are not necessarily essential unless it is specifically stated that the constituent element(s) is/are essential in the above embodiment, or unless the constituent element(s) is/are obviously essential in principle. A quantity, a value, an amount, a range, or the like, if specified in the above-described example embodiments, is not necessarily limited to the specific value, amount, range, or the like unless it is specifically stated that the value, amount, range, or the like is necessarily the specific value, amount, range, or the like, or unless the value, amount, range, or the like is obviously necessary to be the specific value, amount, range, or the like in principle. Furthermore, a material, a shape, a positional relationship, or the like, if specified in the above-described example embodiments, is not necessarily limited to the specific shape, positional relationship, or the like unless it is specifically stated that the material, shape, positional relationship, or the like is necessarily the specific material, shape, positional relationship, or the like, or unless the shape, positional relationship, or the like is obviously necessary to be the specific shape, positional relationship, or the like in principle.

For example, in the first embodiment, the piezoelectric element 2 and the piezoelectric element 3 are formed by the same process, but the piezoelectric element 2 and the piezoelectric element 3 may be formed by different processes, respectively. The piezoelectric element 2 and the piezoelectric element 3 may be made of different materials.

The reflection surface portion 41, the upper surface of the piezoelectric element 2, or the upper surface of the recessed portion 14 may have a shape other than the circular shape. The reflection surface portion 41, the upper surface of the piezoelectric element 2, or the upper surface of the recessed portion 14 may have a quadrilateral shape. The upper surface of the piezoelectric element 3 may have a shape other than the ring shape.

Each of the variable focus mirrors of the first to fifth embodiments may be applied to an optical scanning device that scans a light beam. Specifically, a support beam is extended on both sides of the base portion 1 in one direction parallel to the surface of the base portion 1. In this configuration, the base portion 1 is supported at both ends and is swingable around an axis parallel to the one direction. The reflection portion 4 may swing around the axis parallel to the one direction by resonating with the support beam.

What is claimed is:

1. A variable focus mirror comprising:
a base portion having a plate shape with a recessed portion on a back surface, and a thickness of a part of the base portion where the recessed portion is arranged being smaller than a thickness of a part of the base portion outside the recessed portion;
a first piezoelectric element arranged on a front surface of the base portion where the recessed portion is arranged;
a reflection surface portion arranged on the first piezoelectric element, and arranged opposite to the base portion with respect to the first piezoelectric element; and
a second piezoelectric element arranged on the front surface of the base portion, covering the part of the base portion where the recessed portion is arranged and the part of the base portion outside the recessed portion, and separated from the first piezoelectric element,
wherein:
both of a film stress of the first piezoelectric element and a film stress of the second piezoelectric element are tensile stress or both of the film stress of the first piezoelectric element and the film stress of the second piezoelectric element are compression stress:
a notch portion is arranged in a second piezoelectric element;
the notch portion exposes the front surface of the base portion;
the notch portion connects a part of the front surface of the base portion corresponding to a part of the base portion inside the recessed portion with a part of the front surface of the base portion corresponding to the part of the base portion outside the recessed portion; and
a wiring connects the first piezoelectric element with an external circuit, and the wiring is located on the notch portion.

2. The variable focus mirror according to claim 1, wherein:
the reflection surface portion has a circular shape;
a surface of the first piezoelectric element has a circular shape, an upper surface of the recessed portion has a circular shape; and
a center of the surface of the first piezoelectric element and a center of an upper surface of the recessed portion are located at a same position as a center of the reflection surface portion.

3. The variable focus mirror according to claim 2, wherein
a surface of the second piezoelectric element has a point symmetry shape with respect to the center of the reflection surface portion.

4. The variable focus mirror according to claim 2, wherein
a surface of the second piezoelectric element has a ring shape,
a center of the surface of the second piezoelectric element is located at a same position as the center of the reflection surface portion, and
a width of a part of the second piezoelectric element corresponding to the recessed portion in a radial direction is equal to or more than 15% of a radius of the recessed portion.

5.-7. (canceled)

8. The variable focus mirror according to claim 1, further comprising:
a strain gauge arranged on the front surface of the base portion, and configured to detect a curvature of the reflection surface portion,
wherein
a wiring connects the strain gauge with the external circuit, and the wiring is located on the notch portion.

9. The variable focus mirror according to claim 1, further comprising:
a wiring connecting the second piezoelectric element with an external circuit.

10. The variable focus mirror according to claim 1, further comprising:
an insulating film arranged on a surface of the first piezoelectric element and a surface of the second piezoelectric element,
wherein
an opening is arranged on the insulating film, and the opening exposes a part of the base portion located between the first piezoelectric element and the second piezoelectric element.

11. An optical scanning device comprising:
the variable focus mirror according to claim 1,
wherein
the base portion is configured to swing around an axis parallel to the front surface of the base portion.

12. The variable focus mirror according to claim 1, wherein
the notch portion penetrates the second piezoelectric element along a direction perpendicular to a direction extending the second piezoelectric element.

13. A variable focus mirror comprising:
a base portion having a plate shape with a recessed portion on a back surface, and a thickness of a part of the base portion where the recessed portion is arranged being smaller than a thickness of a part of the base portion outside the recessed portion;
a first piezoelectric element arranged on a front surface of the base portion where the recessed portion is arranged;
a reflection surface portion arranged on the first piezoelectric element, and arranged opposite to the base portion with respect to the first piezoelectric element; and
a second piezoelectric element arranged on the front surface of the base portion, covering the part of the base portion where the recessed portion is arranged and the part of the base portion outside the recessed portion, and separated from the first piezoelectric element,
wherein:
both of a film stress of the first piezoelectric element and a film stress of the second piezoelectric element are tensile stress or both of the film stress of the first piezoelectric element and the film stress of the second piezoelectric element are compression stress;
a notch portion is arranged in a second piezoelectric element;
the notch portion exposes the front surface of the base portion;
the notch portion connects a part of the front surface of the base portion corresponding to a part of the base portion inside the recessed portion with a part of the front surface of the base portion corresponding to the part of the base portion outside the recessed portion; and
the first piezoelectric element extends to the part of the base portion outside the recessed portion through the notch portion.

14. The variable focus mirror according to claim 13, wherein
the notch portion penetrates the second piezoelectric element along a direction perpendicular to a direction extending the second piezoelectric element.
